(19) United States
(12) Patent Application Publication
(10) Pub. No.: US 2023/0395416 A1
(43) Pub. Date: Dec. 7, 2023

(54) LOAD PORT AND METHOD OF MOVING STAGE OF LOAD PORT

(71) Applicant: Sinfonia Technology Co., Ltd., Tokyo (JP)

(72) Inventors: Tatsuru Ogawa, Tokyo (JP); Yuki Ishihara, Tokyo (JP); Shinpei Kogiso, Tokyo (JP); Tatsuya Miura, Tokyo (JP); Atsushi Suzuki, Tokyo (JP); Yuki Matsumoto, Tokyo (JP)

(21) Appl. No.: 18/205,874

(22) Filed: Jun. 5, 2023

(30) Foreign Application Priority Data
Jun. 7, 2022 (JP) 2022-092421

(51) Int. Cl. H01L 21/677

(52) U.S. Cl. CPC H01L 21/67775; H01L 21/67778; H01L 21/67772; H01L 21/67793

(57) ABSTRACT

A load port for loading and unloading substrates between a transport chamber and a storage container includes: a plate-like portion constituting a wall surface of the transport chamber and including an opening in communication with an interior of the transport chamber; a stage configured to mount the storage container thereon such that a lid of the storage container faces a door of the opening; and a controller configured to control a driving device that moves the stage forward and rearward with respect to the plate-like portion, wherein the controller is further configured to control, when moving the stage toward the plate-like portion, the driving device to: apply a first thrust directed toward the plate-like portion to the stage until immediately before the stage reaches a predetermined position; and then apply a second thrust, which is greater than the first thrust and directed toward the plate-like portion, to the stage.

### CROSS-REFERENCE TO RELATED APPLICATION

This application is based upon and claims the benefit of priority from Japanese Patent Application No. 2022-092421, filed on Jun. 7, 2022, the entire contents of which are incorporated herein by reference.

### TECHNICAL FIELD

The present disclosure relates to a load port for loading and unloading a substrate between a transport chamber and a storage container in a state where the load port is disposed adjacent to the transport chamber, and a method of moving a stage of the load port.

### BACKGROUND

Conventionally, semiconductors have been manufactured by executing various processes on substrates. In recent years, with a progress of high integration of devices and miniaturization of circuits, it is required to maintain a high degree of cleanliness around the substrates to prevent particles and moisture from adhering to surfaces of substrates. In addition, in order to prevent changes in surface properties such as oxidation of the surfaces of the substrates, a vicinity of the substrates is made into an atmosphere of nitrogen, which is an inert gas, or made into a vacuum state.

In order to appropriately maintain the atmosphere in the vicinity of substrates, the substrates are managed in a state of being accommodated in an airtight storage pod called a front-opening unified pod (FOUP), and an interior of the storage pod is filled with nitrogen. In addition, an equipment front end module (EFEM) as disclosed in Patent Document 1 is used to deliver the substrates between a processing apparatus that processes the substrates and the FOUP. The EFEM constitutes a substantially closed transport chamber inside a housing and includes a load port, which functions as an interface with the FOUP and is disposed on one of opposite wall surfaces of the housing.

In the EFEM disclosed in Patent Document 1, the load port includes a stage on which the FOUP is mounted, and the stage is configured to be movable forward and rearward with respect to an opening in a wall surface of the processing apparatus between a predetermined DOCK position where a lid of the FOUP is close to the opening in the wall surface and an UNDOCK position where the lid is spaced a predetermined distance from the opening in the wall surface than the DOCK position. In addition, the lid of the FOUP is configured to be able to open and close an opening formed at a rear end of a main body of the FOUP.

### PRIOR ART DOCUMENT

### Patent Document

Patent Document 1: Japanese Patent Laid-open Publication No. 2016-178133

Semiconductor Equipment and Materials International (SEMI) standard stipulates that when the stage on which the FOUP is mounted is moved to the DOCK position, a thrust that presses the rear end of the main body of the FOUP against a peripheral portion of the opening in the wall surface should be at least a predetermined magnitude. Therefore, conventionally, the stage at the UNDOCK position has been moved to the DOCK position by a thrust of the predetermined magnitude or more, which is required at the DOCK position, and then, the rear end of the main body of the FOUP has been pressed against the peripheral portion of the opening in the wall surface.

However, when the thrust at the time of moving the stage from the UNDOCK position to the DOCK position is too large, there is a problem that the substrates accommodated in the FOUP move due to an inertial force when the stage starts to move and when the stage reaches the DOCK position and stops the movement of the stage.

In the past, circular substrates with a diameter of 300 mm were used, but in recent years, for example, rectangular substrates of 515 mm×510 mm and rectangular substrates of 600 mm×600 mm have been used. Thus, since substrates are being enlarged to increase a weight of the substrates accommodated in the FOUP, it is particularly problematic that the thrust when moving the stage to the DOCK position needs to be increased.

### SUMMARY

The present disclosure provides a load port and a method of moving a stage of the load port, which can prevent substrates accommodated in a storage container from moving, for example, when moving the stage on which the storage container is mounted from an UNDOCK position to a DOCK position.

In view of the foregoing, the present disclosure takes the following measures.

That is, a load port according to the present disclosure is a load port for loading and unloading substrates between a transport chamber and a storage container in a state where the load port is disposed adjacent to the transport chamber, the load port comprising: a plate-like portion constituting a portion of a wall surface of the transport chamber and including an opening in communication with an interior of the transport chamber; a stage configured to mount the storage container on the stage such that a lid configured to open and close the storage container faces a door configured to open and close the opening; and a controller configured to control a driving device configured to move the stage on which the storage container is mounted forward and rearward with respect to the plate-like portion, wherein the controller is further configured to control, when moving the stage toward the plate-like portion, the driving device to: apply a first thrust, which is directed toward the plate-like portion, to the stage until immediately before the stage reaches a predetermined position; and apply a second thrust, which is greater than the first thrust and is directed toward the plate-like portion, to the stage after the stage reaches the predetermined position.

With the configuration described above, when moving the stage toward the predetermined position, compared to a case where the stage is moved to the predetermined position by a large thrust required to press a rear end of the storage container against a peripheral portion of the opening in the wall surface, an amount of change in thrust acting on the stage when the stage is switched from a stopped state to a moving state and when the stage is switched from the moving state to the stopped state is reduced. Therefore, the substrates accommodated in the storage container can be prevented from moving due to an inertial force.

In the load port according to the present disclosure, the predetermined position may be a position where the stage is disposed when the substrates are loaded and unloaded between the transport chamber and the storage container, and the controller may be further configured to apply the first thrust, which is directed toward the plate-like portion, to the stage from when the stage on which the storage container is mounted starts to move until immediately before the stage reaches the predetermined position.

With the configuration described above, a constant and relatively small thrust acts on the stage from when the stage starts to move until immediately before the stage reaches the predetermined position. Therefore, the number of times of switching the thrust is reduced so that the substrates accommodated in the storage container can be effectively prevented from moving due to an inertial force.

The load port according to the present disclosure may further include a shock absorber configured to reduce a speed of the stage before the stage reaches the predetermined position.

With the configuration described above, the speed of the stage can be reduced before the stage reaches the predetermined position, and a shock caused by the reduction in speed can be absorbed. Therefore, the substrates accommodated in the storage container can be effectively prevented from moving due to an inertial force.

In the load port according to the present disclosure, the driving device may include an operation-switching solenoid valve configured to switch a moving direction of the stage, and a thrust-switching solenoid valve configured to switch a magnitude of thrust applied to the stage.

With the configuration described above, the magnitude of the thrust acting on the stage can be easily switched.

In the load port according to the present disclosure, the stage may be provided with a lock unit, and the lock unit may include: a first locker which is engaged with a first recess provided in a bottom surface of the storage container to fix the storage container to the stage at least in an up-down direction; and a second locker which is engaged with a second recess provided in the bottom surface of the storage container to restrict a movement of the storage container with respect to the stage at least in a horizontal direction.

With the configuration described above, since a fixing force between the stage and the storage container is increased, the storage container can be suppressed from deviating from the stage, for example, even when the second thrust acts on the stage after the stage reaches the predetermined position and the rear end of the storage container is pressed against the peripheral portion of the opening in the wall surface.

A method of moving a stage in a load port according to the present disclosure is a method of moving a stage in a load port, wherein the load port is configured to load and unload a substrate between a transport chamber and a storage container in a state where the load port is disposed adjacent to the transport chamber, wherein an opening is formed in a plate-like portion constituting a portion of a wall surface of the transport chamber, and wherein the stage on which the storage container is mounted is moved toward the plate-like portion such that a lid configured to open and close the storage container faces a door configured to open and close the opening, the method including: applying a first thrust, which is directed toward the plate-like portion, to the stage until immediately before the stage reaches a predetermined position; and applying a second thrust, which is greater than the first thrust and is directed toward the plate-like portion, to the stage after the stage reaches the predetermined position.

With the configuration described above, when moving the stage toward the predetermined position, compared to a case where the stage is moved to the predetermined position by a large thrust required to press a rear end of the storage container against a peripheral portion of the opening of the wall surface, an amount of change in thrust acting on the stage when the stage is switched from a stopped state to a moving state and when the stage is switched from the moving state to the stopped state is reduced. Therefore, the substrates accommodated in the storage container can be prevented from moving due to an inertial force.

### BRIEF DESCRIPTION OF DRAWINGS

The accompanying drawings, which are incorporated in and constitute a part of the specification, illustrate embodiments of the present disclosure.

FIG. 1 is a perspective view of an EFEM 1 equipped with load ports 3 according to an embodiment of the present disclosure.

FIG. 2 is a side view of the EFEM 1.

FIG. 3 is a perspective view of the load port 3.

FIG. 4 is a front view of the load port 3.

FIG. 5 is a rear view of the load port 3.

FIG. 6 is a side cross-sectional view of the load port 3.

FIG. 7 is a side cross-sectional view illustrating a state in which a FOUP 6 is moved toward a panel 31 from the state in FIG. 6.

FIG. 8 is a side cross-sectional view illustrating a state in which, together with a lid 62 of the FOUP 6, a door 51 is spaced apart from the panel 31 from the state in FIG. 7.

FIG. 9 is a side cross-sectional view illustrating a state in which, together with the lid 62 of the FOUP 6, the door 51 is moved downward from the state illustrated in FIG. 8.

FIGS. 10A and 10B are schematic views for explaining a driving mechanism 80 configured to move a stage 34.

FIG. 11 is a circuit diagram for explaining an operation of the driving mechanism 80.

FIG. 12 is a circuit diagram for explaining the operation of the driving mechanism 80.

FIG. 13 is a circuit diagram for explaining the operation of the driving mechanism 80.

FIG. 14 is a control block diagram for the load port 3 in FIG. 1.

FIG. 15 is a schematic view for explaining an operation of moving the stage 34.

FIG. 16 is a diagram showing a change in thrust when moving the stage 34.

FIG. 17 is a diagram showing a modification of the change in thrust when moving the stage 34.

FIGS. 18A and 18B are schematic views for explaining a lock unit 134.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings.

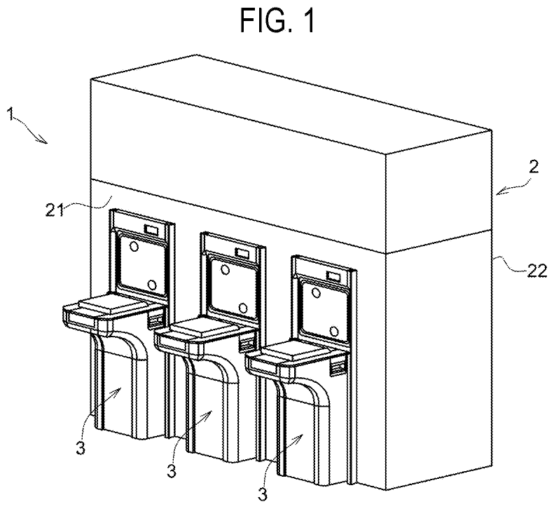

FIG. 1 illustrates load ports 3 of the present embodiment and an EFEM 1 including the same. The EFEM 1 includes three load ports 3 arranged side by side and connected to a front surface 21 constituting a portion of a wall surface of a transport chamber 2 constituting a box-shaped housing.

Here, in the present embodiment, an orientation of a side to which the load ports 3 are connected when viewed from the transport chamber 2 is defined as a front side, an orientation of a rear surface 22 opposite the front surface 21 is defined as a rear side, and a direction orthogonal to a front-rear direction and a vertical direction is defined as a lateral direction. That is, the three load ports 3 are arranged side by side in the lateral direction.

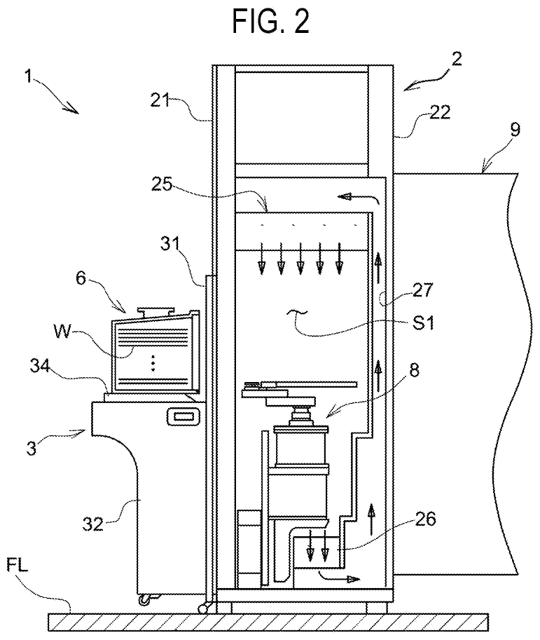

FIG. 2 is a side view illustrating the load port 3 and the EFEM 1 including the same. As described above, the load port 3 is connected to the front surface 21 of the transport chamber 2. The load port 3 has a panel 31 as a plate-like portion on the rear side, and the panel 31 is integrated with the front surface 21 to constitute a portion of the wall surface of the EFEM 1. The load port 3 is provided with a stage 34 protruding forward from the panel 31, and on the stage 34, a FOUP 6 as a storage container for accommodating substrates W can be placed.

The EFEM 1 is installed on a floor FL, and is configured such that a processing apparatus 9 configured to perform a predetermined process on the substrates W is connectable to the rear surface 22. An internal space S1 of the transport chamber 2 and the processing apparatus 9 are in communication with each other via a gate valve (not illustrated) provided on the rear surface 22 of the EFEM 1. In addition, a transport device 8 configured to transport the substrates W is provided in the internal space S1 of the transport chamber 2. By using the transport device 8, it is possible to transport the substrates W between the FOUP 6 installed in the load port 3 and the processing apparatus 9.

The transport chamber 2 is configured such that the internal space S1 of the transport chamber 2 is substantially sealed by connecting the load port 3 and the processing apparatus 9 to the transport chamber 2. Thus, by performing purging with dry nitrogen gas by using a gas supply port and a gas discharge port, which are not illustrated, it is possible to increase a concentration of nitrogen gas in the internal space S1 of the transport chamber 2. In addition, the transport chamber 2 is configured such that a fan filter unit 25 is provided in an upper portion of the transport chamber 2 to discharge a gas downward, a chemical filter 26 provided in a lower portion thereof suctions the gas, and the gas is returned to the fan filter unit 25 in the upper portion thereof via a circulation duct 27 provided adjacent to an inner side of the rear surface 22. Therefore, it is possible to form a downflow, which is an air flow flowing downward from above, in the transport chamber 2 and to maintain the gas inside the transport chamber 2 in a clean state by circulating the gas. In addition, even when particles that contaminate surfaces of substrates W exist in the internal space S1 of the transport chamber 2, the particles are pushed downward by the downflow, which makes it possible to suppress the particles from adhering to the surfaces of the substrates W during transportation. In addition, since a residual gas caused by the processing apparatus 9 can be also captured by the chemical filter 26, it is possible to keep the inner space S1 of the transport chamber 2 in a cleaner state.

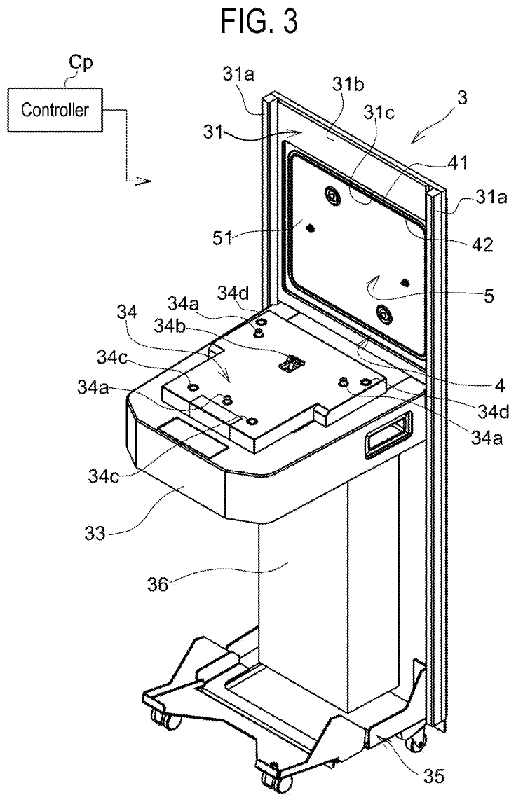

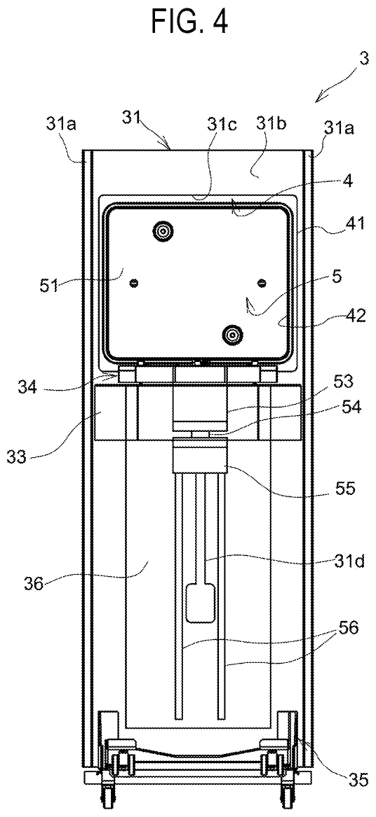

FIGS. 3 to 5 illustrate a perspective view of the load port 3, a front view of the load port 3 when viewed from the front side, and a rear view of the load port 3 when viewed from the rear side, respectively. Hereinbelow, a configuration of the load port 3 will be described with reference to these drawings. In addition, these drawings illustrate a state in which an external cover 32 (see FIG. 2) located below the stage 34 is removed and a portion of an internal structure is exposed.

In the load port 3, the panel 31 vertically erects from a rear side of a leg part 35, which is provided with casters and installation legs, and a horizontal base 33 is oriented forward from a height position of about 60% of the panel 31. On a top of the horizontal base 33, the stage 34 configured to mount the FOUP 6 (see FIG. 2) thereon is provided.

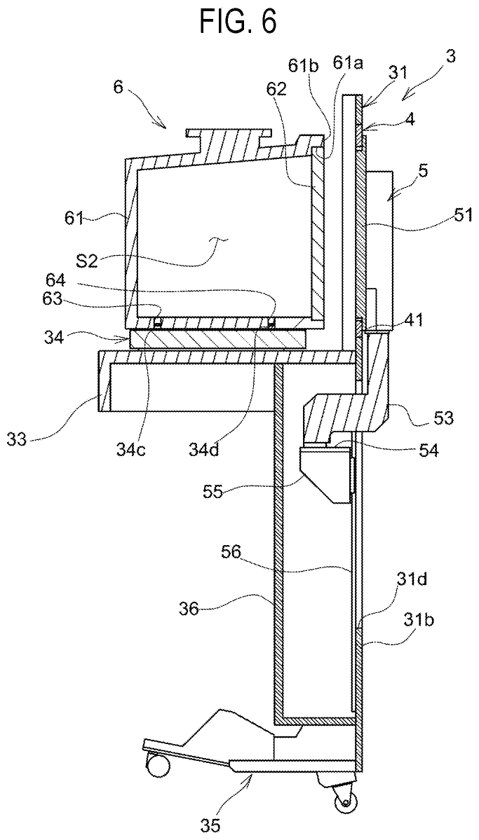

As schematically illustrated in FIG. 6, the FOUP 6 includes a main body 61 having an internal space S2 configured to accommodate the substrates W (see FIG. 2), and a lid 62 configured to be capable of opening and closing an opening 61a, which is provided at a rear end of the main body 61 and serves as a load/unload port for the substrates W. The FOUP 6 is configured such that the lid 62 faces the panel 31 when the FOUP 6 is correctly mounted on the stage 34.

Returning back to FIGS. 3 to 5, positioning pins 34a configured to position the FOUP 6 and a lock claw 34b configured to fix the FOUP 6 to the stage 34 are provided on the stage 34. By performing a locking operation, the lock claw 34b can guide and fix the FOUP 6 to an appropriate position in cooperation with the positioning pins 34a, and by performing an unlocking operation, the lock claw 34b can put the FOUP 6 into a state in which the FOUP 6 is spaced apart from the stage 34.

In addition, the stage 34 is provided with two gas supply nozzles 34c constituting a gas supply mechanism for supplying a gas into the FOUP 6 (see FIG. 2) and two gas discharge nozzles 34d constituting a gas discharge mechanism for discharging a gas from the FOUP 6. These nozzles are normally located below a top surface of the stage 34, and when used, move upward to be respectively connected to gas supply valves 63 and gas discharge valves 64 (see FIG. 6) provided in the FOUP 6. Thus, it is possible to perform gas purging by supplying a gas such as dry nitrogen gas to the internal space S2 (see FIG. 6) of the FOUP 6 from the gas supply nozzles 34c via the gas supply valves 63 and by discharging the gas in the internal space S2 from the gas discharge nozzles 34d via the gas discharge valves 64. In addition, by causing a gas supply amount to be more than a gas discharge amount, it is possible to implement a positive pressure setting in which a pressure in the internal space S2 is higher than an external pressure or a pressure in the internal space S1 (see FIG. 2) of the transport chamber 2.

The stage 34 is also configured to be movable in the front-rear direction in a state in which the FOUP 6 (see FIG. 6) is mounted thereon. A configuration for moving the stage 34 in the front-rear direction will be described in detail later.

The panel 31 of the load port 3 includes two columns 31a erecting on both sides, a panel main body 31b supported by the columns 31a, and a window unit 4 installed on a window 31c opened in a substantially rectangular shape in the panel main body 31b. Here, the term “substantially rectangular” as used in the present embodiment refers to a shape in which a basic shape is a rectangle having four sides and four corners are smoothly connected by arcs.

The window unit 4 is provided at a position facing the lid 62 (see FIG. 6) of the FOUP 6 described above, and has a substantially rectangular opening 42 formed inside a frame 41. In the present embodiment, the frame 41 is a peripheral portion of the opening 42. Therefore, the internal space S1 of the transport chamber 2 can be opened via the opening 42. In addition, the load port 3 includes an opening/closing mechanism 5 configured to open and close the opening 42.

The opening/closing mechanism 5 includes a door 51 configured to open and close the opening 42, a support frame 53 configured to support the door 51, a movable block 55 configured to support the support frame 53 to be movable in the front-rear direction via a slide support 54, and a slide rail 56 configured to support the movable block 55 to be movable in an up-down direction with respect to the panel main body 31b. As illustrated in FIG. 6, the support frame 53 supports a lower rear portion of the door 51, and has a substantially crank shape extending downward and protruding forward from the panel main body 31b via a slit-shaped insertion hole 31d provided in the panel main body 31b. The slide support 54, the movable block 55, and the slide rail 56, which are configured to support the support frame 53, are provided in front of the panel main body 31b. That is, since a sliding location for moving the door 51 is disposed outside the transport chamber 2 and the insertion hole 31d is made small in a slit shape, even when particles are generated in this location, it is possible to suppress the particles from entering into the transport chamber 2.

In addition, actuators (not illustrated) configured to move the door 51 in the front-rear direction and the up-down direction are provided for respective directions, and by providing drive commands from a controller Cp to the actuators, the door 51 can be moved in the front-rear direction and the up-down direction.

In addition, a cover 36 extending downward from directly below the horizontal base 33 is provided in front of the panel main body 31b, and the support frame 53, the slide support 54, the movable block 55, and the slide rail 56 are covered and sealed by the cover 36. Therefore, although the insertion hole 31d is formed in the panel main body 31b, a gas in the transport chamber 2 (see FIG. 2) is prevented from flowing out via the insertion hole 31d.

The door 51 includes a connecting mechanism 52 configured to perform a latching operation for opening and closing the lid 62 (see FIG. 6) of the FOUP 6 or to hold the lid 62. With the connecting mechanism 52, the lid 62 can be brought into an openable state by performing the latching operation of the lid 62, and the lid 62 can be connected to the door 51 to be in an integrated state. Conversely, a connection between the lid 62 and the door 51 can be released, and the lid 62 can be attached to the main body 61 to be in a closed state.

The load port 3 of the present embodiment operates when drive commands are provided to respective components by the controller Cp illustrated in FIG. 3. Hereinafter, an operation example using the load port 3 of the present embodiment will be described below with reference to FIGS. 6 to 9.

FIG. 6 illustrates a state in which the FOUP 6 is mounted on the stage 34 and spaced apart from the panel 31. In this state, since the door 51 abuts a rear surface of the frame 41 constituting the window unit 4, no gap is formed between the window frame 41 and the door 51, thereby achieving sealing. Therefore, even when the internal space S1 of the transport chamber 2 is filled with nitrogen gas or the like, an outflow of the gas to the outside and an inflow of a gas from the outside into the internal space S1 can be suppressed.

Although not illustrated in FIG. 6, the FOUP 6 is appropriately positioned and fixed to the stage 34 by the locking operation of the lock claw 34b (see FIG. 3) and the positioning operation of the positioning pins 34a.

In addition, the gas supply nozzles 34c and the gas discharge nozzles 34d provided in the stage 34 protrude upward and are respectively connected to the gas supply valves 63 and the gas discharge valves 64 provided in the FOUP 6. Thereafter, fresh dry nitrogen gas is supplied from the gas supply nozzles 34c via the gas supply valves 63, and a gas remaining in the internal space S2 until then is discharged from the gas supply nozzles 34c via the gas discharge valves 64. By performing gas purging as described above, the internal space S2 is filled with nitrogen gas, and the pressure in the internal space S2 is made to be higher than that of the internal space S1 of the transport chamber 2.

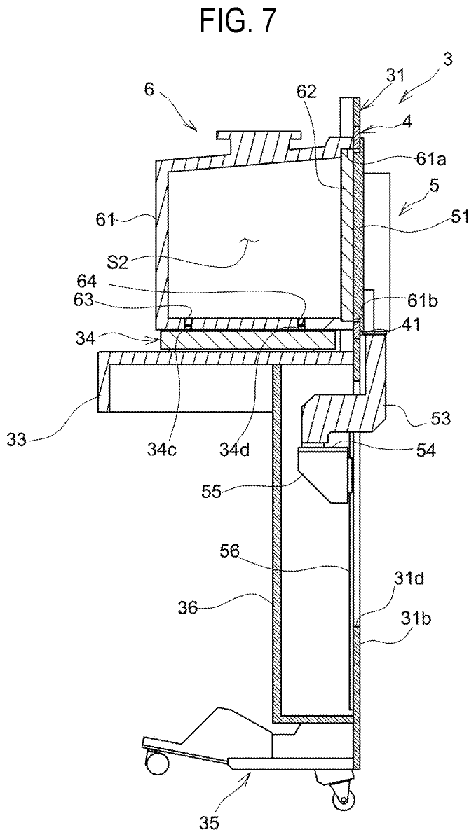

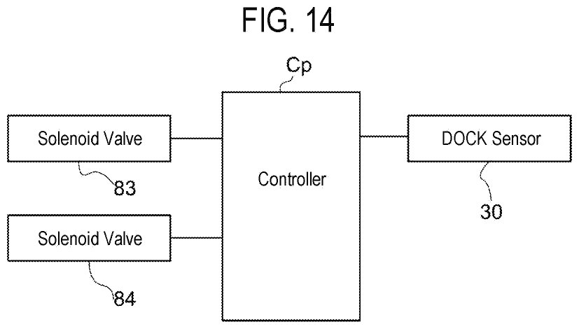

Subsequently, as illustrated in FIG. 7, the stage 34 is moved rearward to cause the rear end of the main body 61 of the FOUP 6 to abut on the frame 41 (the peripheral portion of the opening 42). In the present embodiment, a position where the rear end of the main body 61 of the FOUP 6 abuts on the frame 41 will be called a DOCK position. The load port 3 includes a DOCK sensor 30 (see FIG. 14) configured to detect whether the stage 34 is located at the DOCK position.

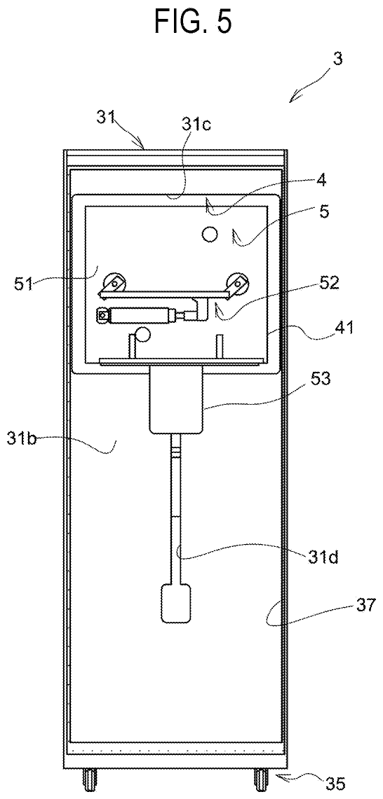

In addition, by operating the connecting mechanism 52 (see FIG. 5) provided on the door 51, the lid 62 is brought into an unlatched state to make the lid 62 separable from the main body 61 of the FOUP 6, and the lid 62 is integrally held by the door 51.

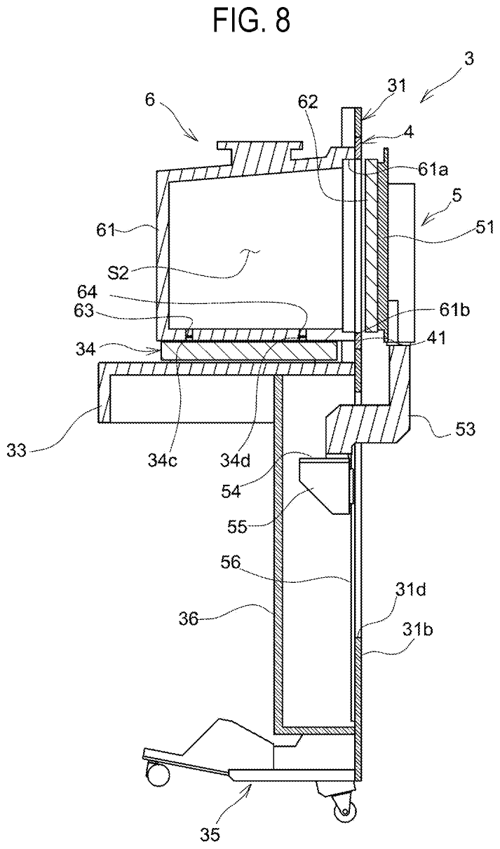

From this state, the door 51 is moved rearward together with the support frame 53, as illustrated in FIG. 8. Thus, the lid 62 of the FOUP 6 can be spaced apart from the main body 61 to open the internal space S2. At this time, since the rear end of the main body 61 of the FOUP 6 is firmly in close contact with the window unit 4, it is possible to suppress the outflow and inflow of gas between the transport chamber 2 and the FOUP 6 and the outside.

In addition, since the pressure of the FOUP 6 is set to be high, a gas flow from the internal space S2 of the FOUP 6 into the transport chamber 2 is generated. Therefore, it is possible to suppress particles from entering from the transport chamber 2 into the FOUP 6 and to keep the inside of the FOUP 6 clean. In addition, for the purpose of preventing the entry of particles, a gas may be continuously supplied at a low flow rate via the gas supply nozzles 34c.

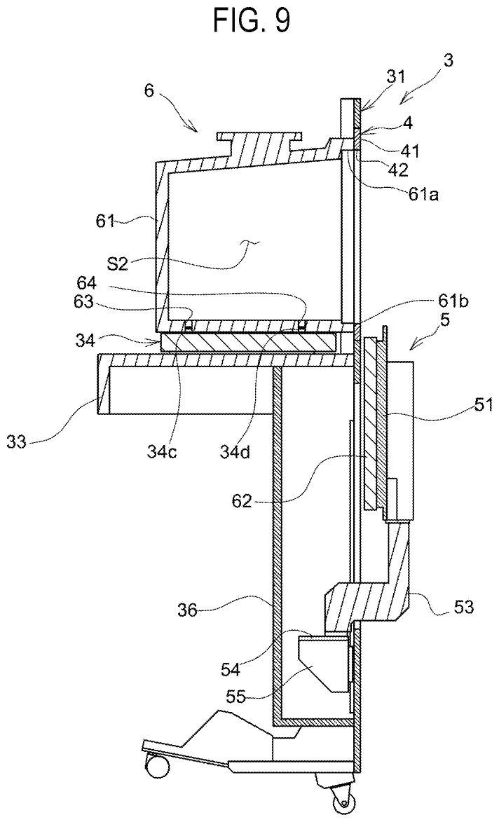

Subsequently, as illustrated in FIG. 9, the door 51 is moved downward together with the support frame 53. Thus, a rear side of the opening 61a serving as the load/unload port of the FOUP 6 can be largely opened, so that the substrates W can be moved between the FOUP 6 and the processing apparatus 9 (see FIG. 2). Since the mechanism for moving the door 51 is entirely covered with the cover 36 as described above, it is possible to suppress leakage of the gas in the transport chamber 2 to the outside.

As described above, while the operation of opening the opening 61a of the FOUP 6 has been described, an operation opposite to that described above may be performed when closing the opening 61a of the FOUP 6.

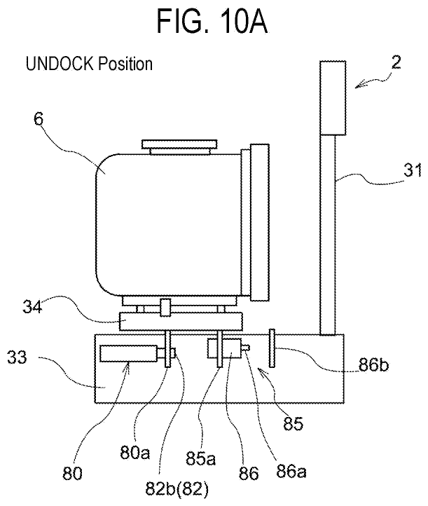

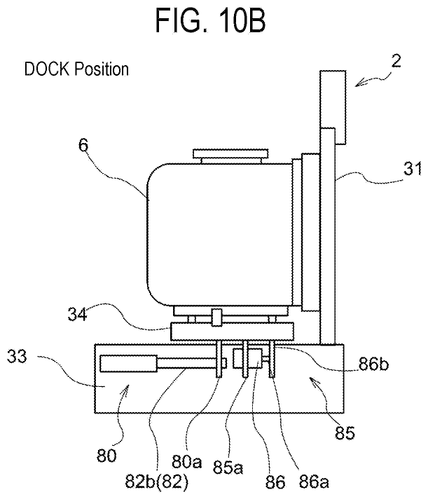

Next, a configuration of a driving device 80 configured to move the stage 34 forward and rearward with respect to the panel 31 will be described with reference to FIGS. 10A to 13.

As illustrated in FIGS. 10A and 10B, the driving device 80 is provided inside the horizontal base 33 disposed below the stage 34 of the load port 3. The driving device 80 is connected to the stage 34 by a support 80a. Therefore, the driving device 80 is capable of moving the stage 34 forward and rearward with respect to the panel 31 by changing a distance between the support 80a and the panel 31.

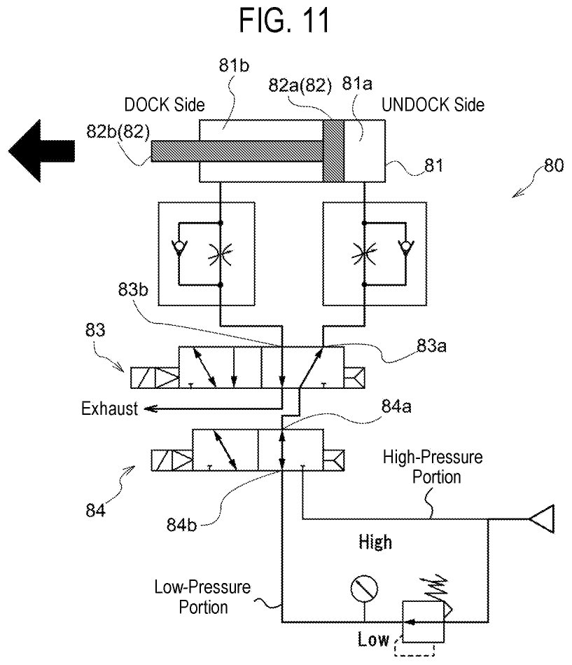

As illustrated in FIGS. 11 to 13, the driving device 80 includes a cylinder 81 and a driving piston 82 movably disposed within the cylinder 81. The driving piston 82 includes a partition 82a that partitions an internal space of the cylinder 81 into a first space 81a and a second space 81b, and a connector 82b that connects the partition 82a and the support 80a. The support 80a is connected to a tip portion of the connector 82b.

The driving device 80 includes an operation-switching solenoid valve 83 configured to switch a moving direction of the stage 34, and a thrust-switching solenoid valve 84 configured to switch a magnitude of thrust applied to the stage 34.

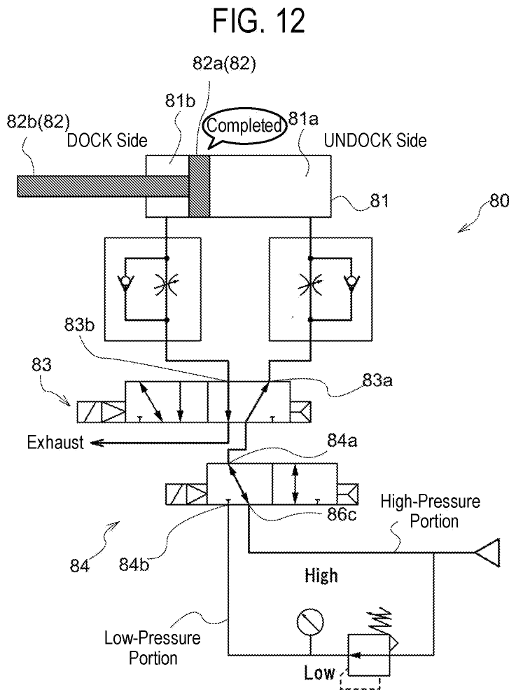

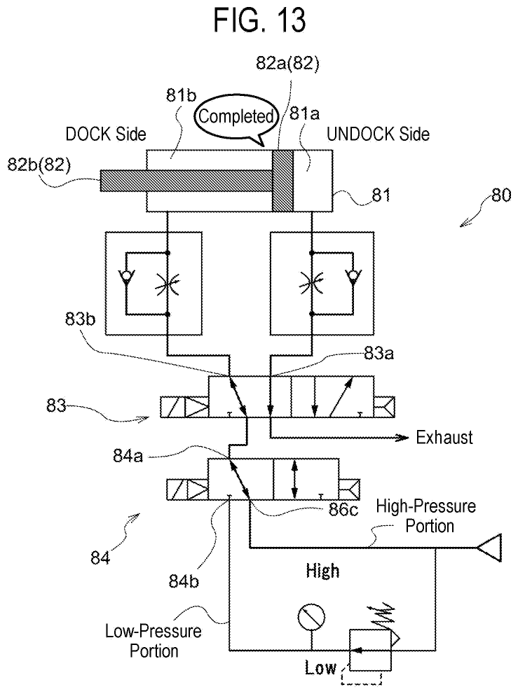

The solenoid valve 83 may be in a first switching state in which a first port 83a connected to the first space 81a is connected to the solenoid valve 84 and a second port 83b connected to the second space 81b is connected to an exhauster (not illustrated) as illustrated in FIGS. 11 and 12, or a second switching state in which the first port 83a connected to the first space 81a is connected to the exhauster and the second port 83b connected to the second space 81b is connected to the solenoid valve 84 as illustrated in FIG. 13.

The solenoid valve 84 may be in a first switching state in which a first port 84a connected to the solenoid valve 83 is connected to a second port 84b connected to a low-pressure portion as illustrated in FIG. 11, or a second switching state in which the first port 84a connected to the solenoid valve 83 is connected to a third port 84c connected to a high-pressure portion as illustrated in FIGS. 12 and 13.

In addition, a regulator is disposed in a circuit of the solenoid valve 84 for thrust switching, forming the low-pressure portion.

In the present embodiment, as described above, the position where the rear end of the main body 61 of the FOUP 6 abuts on the frame 41 is called the DOCK position (a predetermined position at the time of loading and unloading the substrates between the transport chamber 2 and the FOUP 6). In contrast, the position where the rear end of the main body 61 of the FOUP 6 is spaced apart from the frame 41 is called the UNDOCK position.

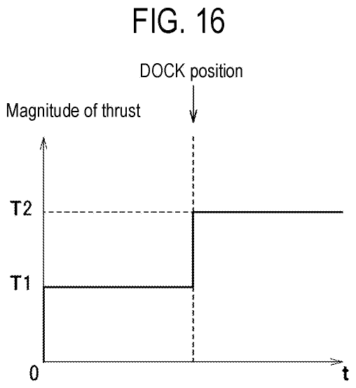

When moving the stage 34 from the UNDOCK position toward the DOCK position, as illustrated in FIG. 11, the driving piston 82 in the cylinder 81 moves toward a DOCK side by a low-pressure gas supplied to the first space 81a in the cylinder 81. At that time, a first thrust T1 (see FIG. 16) based on a pressure of the low-pressure portion acts on the stage 34.

Thereafter, when the stage 34 reaches the DOCK position, as illustrated in FIG. 12, switching is performed such that a high-pressure gas is supplied to the first space 81a in the cylinder 81. At that time, a second thrust T2 (see FIG. 16) based on a pressure of the high-pressure portion acts on the stage 34.

Thereafter, when loading and unloading the substrates between the transport chamber 2 and the FOUP 6 is completed, and when the stage 34 is moved from the DOCK position toward the UNDOCK position, as illustrated in FIG. 13, the driving piston 82 in the cylinder 81 is moved toward an UNDOCK side by the high-pressure gas supplied to the second space 81b in the cylinder 81. At that time, the second thrust T2 (see FIG. 16) based on the pressure of the high-pressure portion acts on the stage 34.

In addition, as illustrated in FIGS. 10A and 10B, a shock absorbing device 85 is provided inside the horizontal base 33 disposed below the stage 34 of the load port 3. The shock absorbing device 85 is connected to the stage 34 by a support 85a.

The shock absorbing device 85 is a so-called damper and includes a cylinder 86, a piston 86a disposed to be movable in the cylinder 86, and a receiving plate 86b disposed near the panel 31. The piston 86a is biased toward the panel 31 by a biasing member (not illustrated) such as a spring accommodated in the cylinder 86.

Therefore, in a case where the stage 34 moves toward the panel 31, when the stage 34 reaches a vicinity of the DOCK position, a tip of the piston 86a is brought into contact with the receiving plate 86b. Thereafter, when the stage 34 moves further toward the panel 31, the piston 86a moves against a biasing force of the biasing member, so that a shock caused by speed reduction of the stage 34 is absorbed. Thereafter, the stage 34 moves to the DOCK position and stops.

As illustrated in FIG. 14, the controller Cp of the load port 3 is configured with, for example, a microcomputer and includes a CPU, a ROM configured to store a program for controlling the operation of the load port 3, and a RAM configured to temporarily store data and the like to be used when executing the program. The operation of the load port 3 is controlled by the controller Cp. The solenoid valve 83, the solenoid valve 84, and the DOCK sensor 30 are connected to the controller Cp.

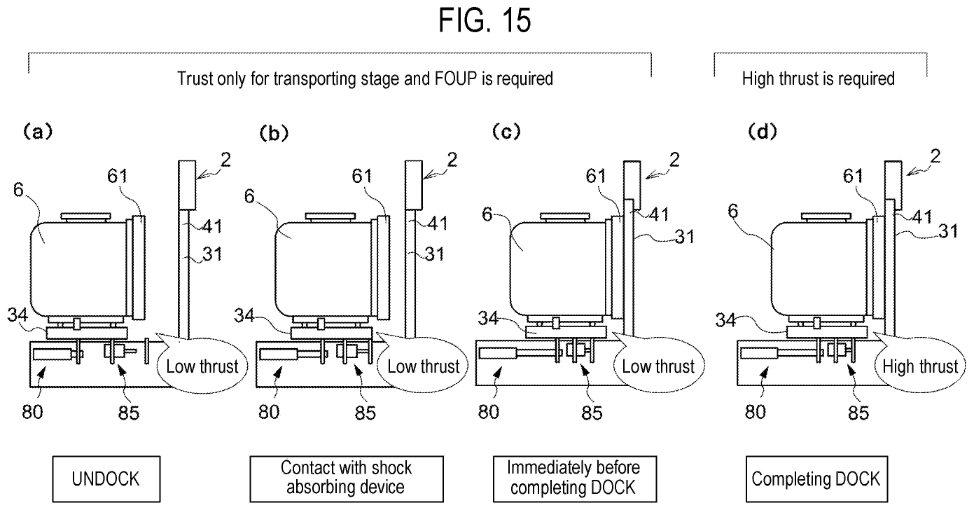

An operation when the stage 34 moves toward the panel 31 will be described with reference to FIG. 15.

As illustrated in (a) of FIG. 15, after the FOUP 6 is mounted on the stopped stage 34, the stage 34 is started to move toward the panel 31. Then, as illustrated in (b) of FIG. 15, the tip of the piston 86a of the shock absorbing device 85 is brought into contact with the receiving plate 86b. Subsequently, when the stage 34 is further moved toward the panel 31, as illustrated in (c) of FIG. 15, the rear end of the main body 61 of the FOUP 6 reaches a position immediately before the DOCK position where the rear end of the main body 61 of the FOUP 6 abuts on the front surface of the frame 41 of the window unit 4. Thereafter, as illustrated in (d) of FIG. 15, the rear end of the main body 61 of the FOUP 6 abuts on the front surface of the frame 41 of the window unit 4, achieving a sealed state.

FIG. 16 shows a change in thrust applied to the stage 34 by the driving device 80. When moving the stage 34 from the UNDOCK position toward the DOCK position, as illustrated in FIG. 16, from when the stage 34 starts to move until immediately before the stage 34 reaches the DOCK position (immediately before the completion of DOCK), the controller Cp applies the first thrust T1 directed toward the panel 31 to the stage 34 to move the stage 34 toward the DOCK position. Thereafter, the controller Cp controls the driving device 80 to apply the second thrust T2, which is directed toward the panel 31 and is greater than the first thrust T1, to the stage 34 after the stage 34 reaches the DOCK position. In the present embodiment, when the DOCK sensor 30 detects that the stage 34 is in the DOCK position and is turned on, the thrust applied to the stage 34 is switched from the first thrust T1 to the second thrust T2. For example, in a case where the DOCK sensor 30 is turned on when the stage 34 reaches the DOCK position, the thrust applied to the stage 34 when the stage 34 reaches the DOCK position is switched from the first thrust T1 to the second thrust T2. In addition, in a case where the DOCK sensor 30 is turned on when the stage 34 reaches a position slightly before the DOCK position, the thrust applied to the stage 34 is switched from the first thrust T1 to the second thrust T2 when the stage 34 reaches the position slightly before the DOCK position.

The SEMI standard stipulates that at the DOCK position, the thrust that presses the rear end of the main body 61 of the FOUP 3 against the front surface of the frame 41 of the window unit 4 should be at least a predetermined magnitude, and the second thrust T2 is set to be a value that satisfies the SEMI standard. The first thrust T1 has a smaller value than that of the second thrust T2. In the present embodiment, the first thrust T1 is set to be approximately half the magnitude of the second thrust T2. With the load port 3 of the present embodiment, an effect of the present disclosure is obtained by setting an amount of change in thrust when the thrust acting on the stage 34 is switched to be smaller than the value of the second thrust T2.

As described above, the load port 3 in the present embodiment is a load port configured to load and unload the substrates between the transport chamber 2 and the FOUP 6 in a state where the load port is disposed adjacent to the transport chamber 2. The load port 3 includes: the panel 31 constituting a portion of the wall surface of the transport chamber 2 and having the opening 42 for opening the inside of the transport chamber 2; the stage 34 configured to mount the FOUP 6 thereon such that the lid 62 configured to open and close the FOUP 6 faces the door 51 configured to open and close the opening 42; and the controller Cp configured to control the driving device 80 configured to move the stage 34 on which the FOUP 6 is mounted forward and rearward with respect to the panel 31. The controller Cp is configured to control, when moving the stage 34 toward the panel 31, the driving device 80 to: apply the first thrust T1, which is directed toward the panel 31, to the stage 34 until immediately before the stage 34 reaches the DOCK position at the time of loading and unloading the substrates between the transport chamber 2 and the FOUP 6; and apply the second thrust T2, which is greater than the first thrust T1 and is directed toward the panel 31, to the stage 34 after the stage 34 reaches the DOCK position.

A stage moving method for use in the load port 3 according to the present embodiment is a method of moving the stage in the load port 3, wherein the load port 3 is configured to load and unload the substrates between the transport chamber 2 and the FOUP 6 in a state where the load port 3 is disposed adjacent to the transport chamber 2, wherein the opening 42 is formed in the panel 31 constituting a portion of the wall surface of the transport chamber 2, and wherein the stage 34 on which the FOUP 6 is mounted is moved toward the panel 31 such that the lid 62 configured to open and close the FOUP 6 faces the door 51 configured to open and close the opening 42, the method including: applying the first thrust T1, which is directed toward the panel 31, to the stage 34 until immediately before the stage 34 reaches the DOCK position; and applying the second thrust T2, which is greater than the first thrust T1 and is directed toward the panel 31, to the stage 34 after the stage 34 reaches the DOCK position.

With the configuration described above, when moving the stage 34 from the UNDOCK position toward the DOCK position, compared to a case where the stage 34 is moved to the DOCK position by a large thrust required to press the rear end of the FOUP 6 against the frame 41 of the window unit 4, the amount of change in thrust acting on the stage 34 when the stage 34 is switched from the stopped state to the moving state and when the stage 34 is switched from the moving state to the stopped state is reduced. Therefore, the substrates accommodated in the FOUP 6 can be prevented from moving due to an inertial force.

In addition, when moving the stage 34 from the UNDOCK position toward the DOCK position, compared to a case where the stage 34 is moved to the DOCK position by a large thrust required to press the rear end of the FOUP 6 against the peripheral portion of the opening 42 of the window unit 4, the thrust at the time of moving the stage 34 toward the peripheral portion of the opening 42 of the window unit 4 is reduced. Therefore, it is possible to prevent, when foreign substances are sandwiched between the stage 34 and the FOUP 6 and the wall surface of the transport chamber 2, the foreign substances from being damaged.

In the load port 3 according to the present embodiment, the controller Cp applies the first thrust T1, which is directed toward the panel 31, to the stage 34 from when the stage 34 on which the FOUP 6 is mounted starts to move until immediately before the stage 34 reaches the DOCK position.

With the configuration described above, a relatively small thrust acts on the stage 34 from when the stage 34 starts to move until immediately before the stage 34 reaches the DOCK position. Therefore, the number of times of switching the thrust is reduced so that the substrates accommodated in the FOUP 6 can be effectively prevented from moving due to an inertial force.

The load port 3 in the present embodiment includes a shock absorbing device 85 configured to reduce a speed of the stage 34 before the stage 34 reaches the DOCK position.

With the configuration described above, the speed of the stage 34 can be reduced before the stage 34 reaches the DOCK position, and the shock caused by the reduction in speed can be absorbed. Therefore, the substrates accommodated in the FOUP 6 can be effectively prevented from moving due to an inertial force.

In the load port 3 of the present embodiment, the driving device 80 includes the operation-switching solenoid valve 83 configured to switch the moving direction of the stage 34 and the thrust-switching solenoid valve 84 configured to switch the magnitude of the thrust applied to the stage 34.

With the configuration described above, the magnitude of the thrust acting on the stage 34 can be easily switched.

The specific configuration of respective component is not limited to the above-described embodiment.

In the above-described embodiment, the driving device 80 is controlled to: when moving the stage 34 toward the panel 31 disposed on the rear side of the load port 3, apply the first thrust T1, which is directed toward the panel 31, to the stage 34 from when the stage 34 starts to move until immediately before the stage 34 reaches the DOCK position; and apply the second thrust T2, which is greater than the first thrust T1 and directed toward the panel 31, to the stage 34 after the stage 34 reaches the DOCK position. However, the present disclosure is not limited thereto. For example, the thrust applied to the stage 34 from when the stage 34 starts to move until immediately before the stage 34 reaches the DOCK position is not necessarily a constant value. In the present disclosure, the thrust applied to the stage 34 is switched from the first thrust T1 to the second thrust T2 after the stage 34 reaches a predetermined position, but the predetermined position is not limited to the position where the stage 34 is disposed at the time of loading and unloading the substrates between the transport chamber 2 and the FOUP 6 (the position where the rear end of the main body 61 of the FOUP 6 abuts on the frame 41 (DOCK position)). In addition, in the load port 3 of the above-described embodiment, a design value of the first thrust T1 is 150 N or less, and a design value of the second thrust T2 is 192 N or more. In an actual control, the first thrust T1 is controlled to be 120.6 N, and the second thrust T2 is controlled to be 192 N or more and have a maximum of 482.5 N.

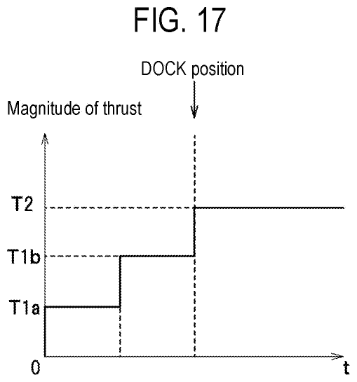

For example, as shown in FIG. 17, a thrust T1a directed toward the panel 31 may be applied to the stage 34 from when the stage 34 starts to move, and then the thrust may be changed from T1a to T1b and the thrust T1b directed toward the panel 31 may be applied to the stage 34 until immediately before the stage 34 reaches the DOCK position. In FIG. 17, although the trust is switched in three stages during the period from when the stage 34 starts to move until immediately before the stage 34 reaches the DOCK position and after the stage 34 reaches the DOCK position, the thrust may be switched in four or more stages.

In the above-described embodiment, the shock absorbing device 85 configured to reduce the speed of the stage 34 before the stage 34 reaches the DOCK position is provided, but the present disclosure is not limited to this. The load port 3 of the present disclosure does not necessarily have the shock absorbing device 85. The shock absorbing device 85 is not limited to a so-called damper. The shock absorbing device 85 may be any device as long as it reduces the speed of the stage 34 moving toward the DOCK position, and may be implemented by inserting a material such as a spring or rubber between the stage 34 and the receiving plate 86b to reduce the speed. In addition, in the above-described embodiment, the driving device 80 uses an air cylinder, but when the driving device 80 is controlled by a motor, the speed of the stage 34 may be reduced by controlling the motor.

In the above-described embodiment, the magnitude of the thrust applied to the stage 34 is switched by the thrust-switching solenoid valve 84, but the present disclosure is not limited thereto. For example, the driving device 80 may have a high-pressure cylinder and a low-pressure cylinder, and the magnitude of the thrust applied to the stage 34 may be switched by changing a cylinder to be used. The driving device 80 may have an air operation valve for thrust switching, and the magnitude of the thrust applied to the stage 34 may be switched by the air operation valve. When the driving device 80 is controlled by a motor, the magnitude of the thrust applied to the stage 34 may be switched by controlling the motor.

In the above-described embodiment, the FOUP 6 is used as a storage container that accommodates the substrates, but even when another type of a storage container is used, it is possible to obtain substantially the same effects by configuring the storage container in the same manner. As the storage container, other than FOUP, for example, an open cassette, a front opening shipping box (FOSB), and the like may be used. The substrates include, for example, wafers, rectangular substrates, tape frame wafers, and the like.

In the above-described embodiment, when moving the stage 34 from the DOCK position toward the UNDOCK position, the stage 34 is moved by the second thrust T2 from when the stage 34 starts to move until the stage 34 reaches the UNDOCK position, but the present disclosure is not limited thereto. In addition, when the stage 34 is moved from the DOCK position toward the UNDOCK position, a problem may also occur in that the substrates accommodated in the FOUP 6 may move due to an inertia force. Therefore, when moving the stage 34 from the DOCK position toward the UNDOCK position, as in the case where the stage 34 is moved from the UNDOCK position toward the DOCK position, the stage 34 may be moved by the first thrust T1 when the stage 34 starts to move, and then the first thrust T1 is switched to the second thrust T2, which is greater than the first thrust T1, to move the stage 34.

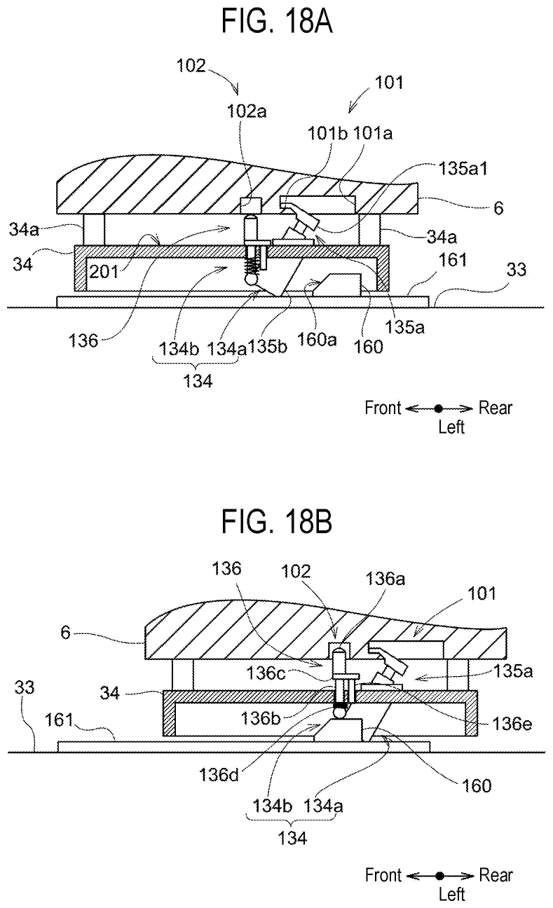

In the load port 3 according to the present embodiment, a lock unit 134 may be provided instead of the lock claw 34b provided on the stage 34. A configuration of the lock unit 134 will be described in detail with reference to FIGS. 18A and 18B. FIGS. 18A and 18B are schematic views for explaining an operation of the lock unit 134 provided on the stage 34.

Various types of retainers having different shapes from each other are provided on a bottom surface of the FOUP 6. One retainer (first retainer) 101 is also called a front retaining feature, and is provided on the bottom surface of the FOUP 6 at a location relatively close to the lid 62. The first retainer 101 may include a recess 101a provided in the bottom surface of the FOUP 6, and an engaging protrusion 101b protruding in a direction approaching the lid 62 from an edge of the recess 101a on a far side from the lid 62. The other retainer (second retainer) 102 is also called a center retaining feature, and is provided substantially in a center of the bottom surface of the FOUP 6 and at a location opposite to the lid 62 with the first retainer 101 interposed therebetween. The second retainer 102 includes a recess 102a.

The lock unit 134 includes: a first locker 134a which is engaged with the first retainer 101 and fixes the FOUP 6, which is mounted at a predetermined position (the position positioned by the positioning pins 34a) of the stage 34, at the predetermined position; and a second locker 134b which is inserted into the second retainer 102 to prevent the engagement of the first locker 134a with respect to the first retainer 101 from being released. In this modification, the first locker 134a is engaged with the first recess 101a provided in the bottom surface of the FOUP 6 to fix the FOUP 6 at least in the up-down direction with respect to the stage 34, and the second locker 134b is engaged with the second recess 102a provided in the bottom surface of the FOUP 6 to restrict a movement of the FOUP 6 at least in the horizontal direction with respect to the stage 34.

The first locker 134a is a so-called bottom clamp, and includes a clamp 135a provided on the stage 34 and a driver 135b configured to drive the clamp 135a to switch its posture between a clamping posture and a releasing posture. The driver 135b is implemented by an appropriate driving mechanism including a cylinder or the like. Here, the “clamping posture” is a posture in which the clamp 135a clamps the engaging protrusion 101b of the first retainer 101 of the FOUP 6 mounted at a predetermined position on the stage 34, and more specifically, a posture in which a hook-shaped portion 135al provided at a tip of the clamp 135a is engaged with the engaging protrusion 101b (the posture illustrated in FIGS. 18A and 18B). On the other hand, the “releasing posture” is a posture in which the clamping state of the clamp 135a is released and an entirety of the clamp 135a is disposed outside the recess 101a (below the bottom surface of the FOUP 6) (not illustrated).

When the clamp 135a is in the clamping posture, the clamp 135a is engaged with the engaging protrusion 135b, a bottom surface of the hook-shaped portion 135a1 and a top surface of the engaging protrusion 101b abut on each other, and a front end surface of the hook-shaped portion 135a1 and a rear end surface of the engaging protrusion 101b are in a state of abutting on each other. As a result, the FOUP 6 mounted at the predetermined position on the stage 34 is fixed to the stage 34 at the predetermined position.

The second locker 135b includes a container separation prevention pin 136 provided on the stage 34 and a push-up block 160 provided on a top surface of the horizontal base 33.

The container separation prevention pin 136 includes an insertion portion 136a and a shaft portion 136b provided below the insertion portion 136a. The shaft portion 136b is inserted into a through-hole provided in the stage 34. A connecting portion between the shaft portion 136b and the insertion portion 136a is provided with a flange 136c protruding in a radial direction, and the flange 136c is engaged with a peripheral portion of the through-hole on the top surface of the stage 34 to prevent the shaft portion 136b from falling from the stage 34. In addition, a spring 136d is provided on a lower portion of the shaft portion 136b (a portion protruding into an internal space of the stage 34) in a contracted state. By being biased downward by the spring 136d, the container separation prevention pin 136 is disposed at a lower position where the flange 136c abuts on the top surface of the stage 34. At this time, an upper end of the insertion portion 136a is disposed at a position lower than the bottom surface of the FOUP 6 mounted on the stage 34 (see FIG. 18A). Hereinafter, this position of the container separation prevention pin 136 is also referred to as a “releasing position.”

When the container separation prevention pin 136 is pushed up by the push-up block 160, which will be described later, the flange 136c is disposed at an upper position where the flange 136c is spaced apart from the top surface of the stage 34. At this time, the insertion portion 136a is partially or entirely inserted into the recess 102a of the second retainer 102 in the FOUP 6 mounted at the predetermined position on the stage 34 (see FIG. 18B). Hereinafter, this position of the container separation prevention pin 136 is also referred to as an “insertion position.” In addition, a guide 136e may be provided on the container separation prevention pin 136 to guide raising and lowering of the container separation prevention pin 136 so that the container separation prevention pin 136 is raised and lowered smoothly between the releasing position and the insertion position. Specifically, for example, the guide 136e may be provided to extend in parallel to the shaft portion 136b from below the flange 136c, and may be inserted into a guide hole provided in the stage 34. With the configuration described above, since the guide 136e is raised and lowered while being guided by the guide hole, the container separation prevention pin 136 is raised and lowered smoothly without axial fluctuation.

The push-up block 160 is a substantially rectangular parallelepiped member, and a front end surface of the push-up block 160 is configured as an inclined surface 160a that inclines rearward as it goes upward. The push-up block 160 is provided on the top surface of the horizontal base 33, specifically, for example, on a linear guide (a linear guide configured to guide the stage 34 moved by the driving device 80) 161 provided on the top surface of the horizontal base 33.

The push-up block 160 is spaced apart from the container separation prevention pin 136 and disposed at a location on the rear side of the container separation prevention pin 136, when the stage 34 is disposed at the UNDOCK position (see FIG. 18A). At this time, the container separation prevention pin 136 is disposed at the releasing position by being biased downward by the spring 136d. When the stage 34 is moved rearward from the UNDOCK position, the push-up block 160 provided on the top surface of the horizontal base 33 moves forward relative to the stage 34 to approach the container separation prevention pin 136, and a lower end of the container separation prevention pin 136 (specifically, a lower end of the shaft portion 136b) and the inclined surface 160a of the push-up block 160 are brought into contact with each other. When the stage 34 is further moved rearward, the container separation prevention pin 136 is guided by the inclined surface 160a and pushed upward. When the stage 34 is disposed at the DOCK position, the container separation prevention pin 136 is in a state of abutting on a top surface of the push-up block 160, and at this time, the container separation prevention pin 136 is disposed at the insertion position (see FIG. 18B).

As described above, when the stage 34 is moved from the UNDOCK position to the DOCK position, the push-up block 160 provided on the horizontal base 33 pushes up the container separation prevention pin 136 provided in the stage 34. Thus, the position of the container separation prevention pin 136 is switched from the releasing position to the insertion position. On the other hand, when the stage 34 is moved from the DOCK position to the UNDOCK position, the push-up block 160 is spaced apart from the container separation prevention pin 136, and the container separation prevention pin 136 is biased downward by the spring 136d, thereby switching from the insertion position to the releasing position.

In the lock unit 134 having the above-described configuration, when the clamp 135a of the first locker 134a is in the clamping posture, the FOUP 6 mounted at a predetermined position on the stage 34 is fixed to the stage 34 at the predetermined position. However, since the clamp 135a abuts on the engaging protrusion 101b from the upper side and the rear side, the clamp 135a is fixed only by friction between the clamp 135a and the engaging protrusion 101b with respect to a tensile force directed forward. Therefore, with the first locker 134a only, for example, when an operator intentionally applies a tensile force that pulls the FOUP 6 forward, the FOUP 6 may move forward with respect to the stage 34 and the engaging protrusion 101b may be disengaged from the clamp 135a (that is, fixing of the FOUP 6 with respect to the stage 34 may be released). Thus, there is a concern that the FOUP 6 may be removed. However, in the lock unit 134, when the stage 34 is disposed at the DOCK position, the container separation prevention pin 136 of the second locker 134b is inserted into the recess 102a of the second retainer 102. As a result, the FOUP 6 is fixed such that the FOUP 6 does not move relative to the stage 34 in the front-rear direction. Therefore, for example, even when an operator intentionally pulls the FOUP 6 forward, the FOUP 6 cannot be removed. That is, with the lock unit 134, intentional removal of the FOUP 6 by an operator can be prevented.

In addition, with the lock unit 134, since it is not necessary to provide a specific driving mechanism (an actuator) for moving the container separation prevention pin 136 of the second locker 134b, a manufacturing cost can be reduced. However, in some cases, instead of the push-up block 160, a driving mechanism for moving the container separation prevention pin 136 may be provided. In such cases, it is sufficient for the driving mechanism to implement simple linear motions. Specifically, the driving mechanism may be implemented by, for example, a linear motion mechanism which is constituted by a drive source, such as a solenoid, a cylinder (air cylinder), and a motor, and a feed screw.

For example, there has conventionally been a mechanism (so-called a center clamp mechanism) that clamps the second retainer 102 with a T-shaped hook to fix the FOUP 6 with respect to the stage 34, but such a mechanism is expensive because it clamps the second retainer 102 by composite motions such as raising, rotating, and lowering. In addition, since a driving mechanism is downsized in order to perform the composite motions in a narrow space, there is also a drawback that the driving mechanism is easily damaged. In contrast, since the lock unit 134 does not require a driving mechanism for performing such complicated operations, it is possible to achieve a low cost, downsizing, high durability, and the like.

In the load port of the modification of the above-described embodiment, the stage 34 is provided with the lock unit 134, and the lock unit 134 includes the first locker 134a which is engaged with the first recess 101a provided in the bottom surface of the FOUP 6 and fixes the FOUP 6 to the stage 34 at least in the up-down direction, and a second locker 134b which is engaged with the second recess 102a provided in the bottom surface of the FOUP 6 and restricts the movement of the FOUP 6 with respect to the stage 34 at least in the horizontal direction.

With the configuration described above, since a fixing force between the stage 34 and the FOUP 6 is increased, it is possible to suppress the FOUP 6 from deviating from the stage 34, for example, even when the second thrust acts on the stage 34 after the stage 34 reaches the DOCK position and the rear end of the FOUP 6 is pressed against the peripheral portion of the opening 42 of the window unit 4.

Other configurations may also be modified in various ways without departing from the spirit of the present disclosure.

According to the present disclosure described above, when a stage on which a storage container is mounted is moved toward a plate-like portion, it is possible to prevent substrates accommodated in the storage container from moving due to an inertial force.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A load port for loading and unloading substrates between a transport chamber and a storage container in a state where the load port is disposed adjacent to the transport chamber, the load port comprising:
a plate-like portion constituting a portion of a wall surface of the transport chamber and including an opening in communication with an interior of the transport chamber;
a stage configured to mount the storage container on the stage such that a lid configured to open and close the storage container faces a door configured to open and close the opening; and
a controller configured to control a driving device configured to move the stage on which the storage container is mounted forward and rearward with respect to the plate-like portion,
wherein the controller is further configured to control, when moving the stage toward the plate-like portion, the driving device to:
apply a first thrust, which is directed toward the plate-like portion, to the stage until immediately before the stage reaches a predetermined position; and
apply a second thrust, which is greater than the first thrust and is directed toward the plate-like portion, to the stage after the stage reaches the predetermined position.

2. The load port of claim 1, wherein the predetermined position is a position where the stage is disposed when the substrates are loaded and unloaded between the transport chamber and the storage container, and
wherein the controller is further configured to apply the first thrust, which is directed toward the plate-like portion, to the stage from when the stage on which the storage container is mounted starts to move until immediately before the stage reaches the predetermined position.

3. The load port of claim 2, further comprising a shock absorber configured to reduce a speed of the stage before the stage reaches the predetermined position.

4. The load port of claim 2, wherein the driving device comprises an operation-switching solenoid valve configured to switch a moving direction of the stage, and a thrust-switching solenoid valve configured to switch a magnitude of thrust applied to the stage.

5. The load port of claim 2, wherein the stage is provided with a lock unit, and
wherein the lock unit comprises:
a first locker which is engaged with a first recess provided in a bottom surface of the storage container to fix the storage container to the stage at least in an up-down direction; and
a second locker which is engaged with a second recess provided in the bottom surface of the storage container to restrict a movement of the storage container with respect to the stage at least in a horizontal direction.

6. The load port of claim 1, further comprising a shock absorber configured to reduce a speed of the stage before the stage reaches the predetermined position.

7. The load port of claim 1, wherein the driving device comprises an operation-switching solenoid valve configured to switch a moving direction of the stage, and a thrust-switching solenoid valve configured to switch a magnitude of thrust applied to the stage.

8. The load port of claim 1, wherein the stage is provided with a lock unit, and
wherein the lock unit comprises:
a first locker which is engaged with a first recess provided in a bottom surface of the storage container to fix the storage container to the stage at least in an up-down direction; and
a second locker which is engaged with a second recess provided in the bottom surface of the storage container to restrict a movement of the storage container with respect to the stage at least in a horizontal direction.

9. A method of moving a stage of a load port, wherein the load port is configured to load and unload substrates between a transport chamber and a storage container in a state where the load port is disposed adjacent to the transport chamber, wherein an opening is formed in a plate-like portion constituting a portion of a wall surface of the transport chamber, and wherein the stage on which the storage container is mounted is moved toward the plate-like portion such that a lid configured to open and close the storage container faces a door configured to open and close the opening, the method comprising:
applying a first thrust, which is directed toward the plate-like portion, to the stage until immediately before the stage reaches a predetermined position; and
applying a second thrust, which is greater than the first thrust and is directed toward the plate-like portion, to the stage after the stage reaches the predetermined position.
